(19) United States
(12) Patent Application Publication
(10) Pub. No.: US 2009/0313731 A1
(43) Pub. Date: Dec. 17, 2009

(54) MOLECULAR MANIPULATOR, A METHOD OF MAKING THE SAME, AND A METHOD OF MOVING A NANOSTRUCTURE

(75) Inventors: Ali Afzali-Ardakani, Yorktown Heights, NY (US); Praveen Chaudhari, Briarcliff Manor, NY (US)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: INTERNATIONAL BUSINESS MACHINES CORPORATION, Armonk, NY (US)

(21) Appl. No.: 12/544,930

(22) Filed: Aug. 20, 2009

Related U.S. Application Data
(62) Division of application No. 10/642,615, filed on Aug. 19, 2003.

(51) Int. Cl. B82B 3/00; B81C 5/00

(52) U.S. Cl. 850/62; 977/895

(57) ABSTRACT

A molecular manipulator includes a light-sensitive molecule, including a double bond, which changes a cis-trans configuration of the double bond in response to illumination by light of a selected wavelength, and a probe, for example, a probe of a scanned-proximity probe microscope, to which the light-sensitive molecule is attached. A method of making the molecular manipulator includes covalently bonding the light-sensitive molecule to the probe. A method of moving a nanostructure includes controllably grasping, moving, and releasing the nanostructure with the molecular manipulator.

This application is a Divisional Application of U.S. patent application Ser. No. 10/642,615, filed on Aug. 19, 2003, having Assignee Docket No. YOR920030023US1.

### BACKGROUND OF THE INVENTION

1. Field of the Invention

The present invention generally relates to a molecular manipulator, a method of making the molecular manipulator, and a method of moving a nanostructure. In particular, the molecular manipulator may include a light-sensitive molecule, which changes its configuration in response to illumination by light of a selected wavelength and is attached to a probe that may be moved.

2. Description of the Related Art

Nanoscience and nanotechnology are active areas of research worldwide. It is anticipated that advances in nanoscience and nanotechnology will inaugurate major changes in the near future in information technology, biotechnology, materials science, and chemical, mechanical, and electrical engineering.

Nanoscience and nanotechnology are concerned with objects having dimensions in the range of nanometers, i.e., 10⁻⁹ meters. Nanostructures, i.e., structures having dimensions in the nanometer range, include atoms, molecules, and clusters of atoms or molecules. These nanostructures may be described as geometric structures, for example, nanotubes or nanospheres.

In situations where precise positioning of a nanostructure is desired, as in the example of positioning a nanotube between two electrical contacts, a probe of an atomic force microscope (AFM) may be used to nudge or move the nanotube to a predetermined position. The position of the nanostructure can be identified by using the tip in an AFM mode, as is well known in the art.

An AFM is a type of scanned-proximity probe microscope that can measure surface topography of a sample on a scale of approximately tenths to thousands of nanometers. Scanned-proximity probe microscopes work by scanning a fine tip over a sample surface and measuring a physical property, e.g., height, optical absorption, magnetism, etc., between the tip and the scanned sample surface. In the case of the AFM, the tip is positioned so close to the sample surface, that atomic forces between the tip and the sample surface cause the tip, which is mounted on a spring-like cantilever, to deflect. The amount of deflection is measured by sophisticated electronics or opto-electronics and corresponds to the height of the tip at a point on the sample surface.

The position of the tip relative to a reference coordinate of the sample surface can be controlled by, for example, piezoceramic controllers, which allow three-dimensional positioning with great accuracy and precision. In the AFM, a feedback circuit can maintain the tip at a constant height in the z direction from the sample surface, as the tip is scanned over the sample surface in the x and y directions.

More precise positioning of a nanostructure would be easier, if the nanostructure could be controllably grasped, moved, and released at a predetermined position.

Molecular synthetic receptors that act as tweezers or clips to grasp and release molecular substrates are known. Molecular tweezers or clips, containing naphthalene and benzene spacer-units, selectively bind electron-deficient, neutral and cationic, molecular substrates in solution. Trimethylene- and dimethylene-bridged clips form complexes with aromatic substrates, and water-soluble clips have been shown to selectively bind N-alkylpyrdinium cations, such as NAD⁺ in aqueous solution. Similarly, soluble molecular tweezers have been synthesized to study the guest-host interaction between chemotherapeutic guests, such as, doxorubicin and daunorubicin, and the host deoxyribonucleic acid (DNA). The dependence of chain length on charge transfer complex formation between N′,N″-poly(methylene)bis-(1-methyl-4,4′-bispryidinium), VCₙV (n=3-8) and 2-naphthol shows that VCₙVs behave effectively as molecular tweezers in solution, when n=7.

However, the grasping and releasing of a molecular substrate by these various soluble molecular tweezers and clips takes place in solution. Hence, these soluble molecular tweezers and clips cannot controllably, accurately, and precisely place the grasped substrate in a predetermined position. In addition, the reaction kinetics of grasping and releasing a substrate can depend on changing the concentration of one or more of the solution's components. Such concentration changes take time.

The grasping and releasing of a nanostructure is more readily controlled by the example of photoinduction of a tweezers-like action by a calixarene-porphrin conjugate upon a quinone substrate.

In addition, a polypeptide chain containing azobenzene groups has been shown to contract and expand, respectively, with optical excitation by different wavelengths. Further, the photo-induced contraction of this polypeptide provides enough force to bend the cantilever of an AFM.

Nanoscience and nanotechnology would greatly benefit from a means to controllably grasp a selected nanostructure, to controllably move the selected nanostructure, and to controllably release the selected nanostructure at a predetermined position.

### SUMMARY OF THE INVENTION

In view of the foregoing and other exemplary problems and disadvantages of conventional techniques, an exemplary aspect of the present invention may include a molecular manipulator that comprises a light-sensitive molecule, which includes a double bond that changes its cis-trans configuration in response to illumination by a selected wavelength of light, and a probe, for example, the probe of an atomic force microscope (AFM), to which the light-sensitive molecule is attached.

Another exemplary aspect of the present invention may include a method of making a molecular manipulator that comprises covalently bonding a light-sensitive molecule, which may grasp a nanostructure upon illumination by a first wavelength of light and release the nanostructure upon illumination by a second wavelength of light, to a probe, for example, a probe of a scanned-proximity probe microscope, such as an AFM.

Another exemplary aspect of the present invention may include a method of moving a selected nanostructure that comprises grasping the selected nanostructure by illuminating a light-sensitive molecule, which is attached to a probe, with a first wavelength of light, moving the selected nanostructure to a predetermined position by moving the probe to the predetermined position, and releasing the selected nanostructure by illuminating the light-sensitive molecule with a second wavelength of light.

In order to attain the above and other advantages and aspects, according to an exemplary embodiment of the present invention, disclosed herein is a molecular manipulator that comprises a light-sensitive molecule, including a double bond, that changes a cis-trans configuration of the double bond in response to illumination by light of a selected wavelength, and a probe to which the light-sensitive molecule is attached.

In another exemplary embodiment of the present invention, the probe comprises one of a tip and a line of a scanned-proximity probe microscope.

In another exemplary embodiment of the present invention, the probe comprises one of silicon, silicon oxide, aluminum oxide, and titanium oxide.

In another exemplary embodiment of the present invention, the light-sensitive molecule comprises an azo compound.

In another exemplary embodiment of the present invention, the light-sensitive molecule further includes two arms, at least one of the two arms including the double bond, and a moiety located between the two arms.

In another exemplary embodiment of the present invention, a first arm of the two arms includes a single azo double bond, and a second arm of the two arms includes other than an azo double bond.

In another exemplary embodiment of the present invention, the light-sensitive molecule comprises a monoazo compound.

In another exemplary embodiment of the present invention, each of the two arms includes an azo double bond.

In another exemplary embodiment of the present invention, the light-sensitive molecule comprises a diazo compound.

In another exemplary embodiment of the present invention, each of the two arms includes an azo double bond comprising a same cis-trans configuration, when illuminated by the light of the selected wavelength.

In another exemplary embodiment of the present invention, each of the two arms includes a first end, which is bonded to the moiety, and a second end, which includes a functional group, R.

In another exemplary embodiment of the present invention, the functional group, R, comprises one of an alkyl, a haloalkyl, an aryl, an alcohol, an ether, an amine, an aldehyde, a ketone, a carboxylic acid, an ester, and an amide.

In another exemplary embodiment of the present invention, the moiety includes a functional group, which covalently bonds to the probe.

In another exemplary embodiment of the present invention, the functional group comprises one of a sulfide, a thiol, and an isonitrile.

In another exemplary embodiment of the present invention, the probe is coated by a coating, to which the functional group of the moiety covalently bonds.

In another exemplary embodiment of the present invention, the coating comprises a metal coating including one of gold, palladium, and platinum.

In another exemplary embodiment of the present invention, the coating comprises one of trichlorosilane and trialkoxylsilane, which coats a probe comprising a conductive metal oxide.

In another exemplary embodiment of the present invention, each of the two arms comprises a different length.

In another exemplary embodiment of the present invention, the two arms form a space between the two arms that is varied by selecting a functional group, R, for each of the two arms.

In another exemplary embodiment of the present invention, a method of making a molecular manipulator includes covalently bonding to a probe, a light-sensitive molecule, including a double bond, that changes a cis-trans configuration of the double bond in response to illumination by light of a selected wavelength.

In another exemplary embodiment of the present invention, the method of making the molecular manipulator further includes coating the probe with a metal coating to which the light-sensitive molecule covalently bonds.

In another exemplary embodiment of the present invention, the method of making the molecular manipulator further includes coating the probe with one of trichlorosilane and trialkoxylsilane, which coats a probe comprising a conductive metal oxide.

In another exemplary embodiment of the present invention, covalently bonding to a probe occurs at a moiety located between two arms of the light-sensitive molecule.

In another exemplary embodiment of the present invention, a space located between the two arms of the light-sensitive molecule may be varied by selecting a functional group, R, for each of the two arms.

In another exemplary embodiment of the present invention, a method of moving a nanostructure includes grasping the nanostructure with a light-sensitive molecule, which is attached to a probe, by illuminating the light-sensitive molecule with light of a first wavelength, moving the nanostructure, which is grasped, to a predetermined position by moving the probe to the predetermined position, and releasing the nanostructure from the light-sensitive molecule by illuminating the light-sensitive molecule with light of a second wavelength.

In another exemplary embodiment of the present invention, the grasping the nanostructure comprises changing a double bond from a trans configuration to a cis configuration within the light-sensitive molecule.

In another exemplary embodiment of the present invention, changing a double bond from a trans configuration to a cis configuration comprises changing an azo double bond from a trans configuration to a cis configuration

In another exemplary embodiment of the present invention, the releasing the nanostructure comprises changing a double bond from a cis configuration to a trans configuration within the light-sensitive molecule.

In another exemplary embodiment of the present invention, changing a double bond from a cis configuration to a trans configuration comprises changing an azo double bond from a cis configuration to a trans configuration

In another exemplary embodiment of the present invention, the method of moving a nanostructure further includes moving the probe into a proximate position with the nanostructure by using an atomic force mode of operation of a scanned-proximity probe microscope.

Thus, various exemplary embodiments of the present invention may provide a molecular manipulator and method of making the same that include a light-sensitive molecule, which changes its cis-trans configuration in response to illumination by light of a selected wavelength and is attached to a probe, for example, a probe of a scanned-proximity probe microscope, and a method of moving a nanostructure by the molecular manipulator.

### BRIEF DESCRIPTION OF THE DRAWINGS

The foregoing and other aspects of the present invention will be better understood from the following detailed description of exemplary embodiments of the present invention with reference to the figures, in which:

FIG. 1A illustrates a light-sensitive molecule 100, which includes two azo double bonds, in an exemplary embodiment of the present invention;

FIG. 1B illustrates a light-sensitive molecule 100, which includes a single azo double bond, in an exemplary embodiment of the present invention;

FIG. 2 illustrates a molecular manipulator 200 that includes the light-sensitive molecule of FIG. 1A and a probe 230, for example, a probe of a scanned-proximity probe microscope, to which the light-sensitive molecule is attached in an exemplary embodiment of the present invention;

FIG. 3 illustrates a flowchart 300 of a method of making the molecular manipulator 200 of FIG. 2 in an exemplary embodiment of the present invention; and

FIG. 4 illustrates a flowchart 400 of a method of moving a nanostructure with the molecular manipulator 200 of FIG. 2 in an exemplary embodiment of the present invention.

### DETAILED DESCRIPTION OF EXEMPLARY EMBODIMENTS OF THE INVENTION

The present invention generally describes various exemplary embodiments of a molecular manipulator and method of making the same.

The molecular manipulator may controllably grasp a nanostructure, controllably move the grasped nanostructure by moving a probe, for example, a probe of a scanned-proximity probe microscope, to a predetermined location, and controllably release the grasped nanostructure at a predetermined position. The molecular manipulator may comprise a light-sensitive molecule, including a double bond that changes its cis-trans configuration in response to illumination by a selected wavelength of light, and a probe, for example, a probe of a scanned-proximity probe microscope, such as an atomic force microscope (AFM), to which the light-sensitive molecule may be attached.

A method of making the molecular scale manipulator may comprise covalently bonding a light-sensitive molecule, which may grasp a nanostructure upon illumination by a first wavelength of light and release the nanostructure upon illumination by a second wavelength of light, to a probe, for example, a probe of a scanned-proximity probe microscope.

A method of moving a selected nanostructure may include bringing the light-sensitive molecule in proximity to a selected nanostructure by moving a probe, for example, a probe of a scanned-proximity probe microscope, to which the light-sensitive molecule may be attached, in proximity to the selected nanostructure, controllably grasping the selected nanostructure by illuminating the light-sensitive molecule with a first wavelength of light, moving the selected nanostructure to a predetermined position by moving the probe to the predetermined position, and releasing the selected nanostructure by illuminating the light-sensitive molecule with a second wavelength of light.

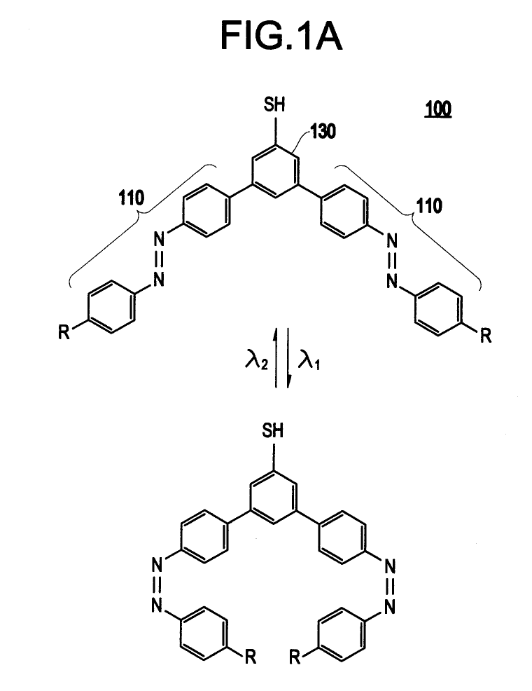

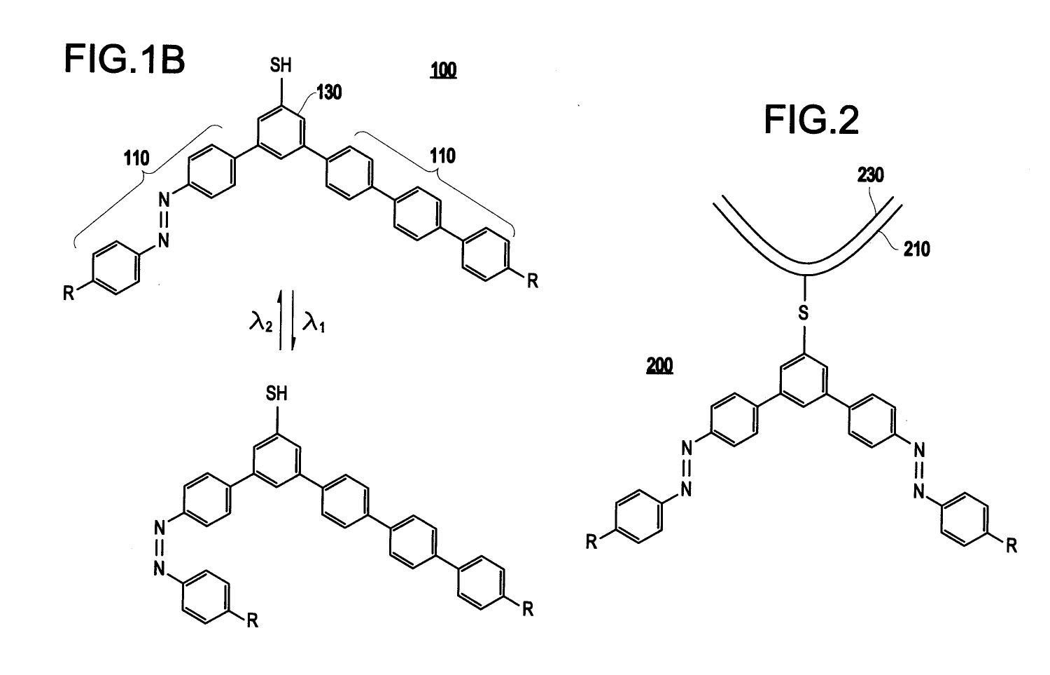

Referring to FIGS. 1A and 1B, a light-sensitive molecule 100 may comprise an azo compound in various exemplary embodiments of the present invention. The light-sensitive molecule 100 may include two arms 110, in which at least one of the two arms may include an azo double bond. In various exemplary embodiments, the light-sensitive molecule 100 may comprise a diazo compound with an azo double bond located in each of the two arms 110, as shown in FIG. 1A, or a monoazo compound with a single azo double bond located in one of the two arms 110, as shown in FIG. 1B. The light-sensitive molecule 100 may further include a moiety 130 to which each of the two arms 110 is bonded.

Each arm of the light-sensitive molecule 100 may be bonded at a first end to the moiety 130 and at a second end to a functional group, R, which may include, for example, alkyls, haloalkyls, aryls, alcohols, ethers, amines, aldehydes, ketones, carboxylic acids, esters, and amides. In various exemplary embodiments, the functional group, R, at the second end of each arm may be the same or different in the two arms 110. The spacing between the two arms 110 may be, for example, varied by using various functional groups, R.

Additionally, the length of each arm of the light-sensitive molecule 100 may be varied by adding various substituents, which include conjugated double bonds, to the first end and/or the second end of each arm. In various exemplary embodiments, ones or more azo double bonds of the light-sensitive molecule 100 may exist in a favored cis-trans configuration, which is dependent upon a wavelength of illuminating light.

As illustrated by FIGS. 1A and 1B, the double bonds of the light-sensitive molecule 100 may each exist in a trans configuration, when illuminated by light of a first wavelength, while the double bonds of the light-sensitive molecule 100 may each exist in a cis configuration, when illuminated by light of a second wavelength.

As shown in FIG. 1A, the moiety 130, which may include conjugated double bonds that form a stable cis or trans configuration, may be located symmetrically between the two arms 110 of the light-sensitive molecule 100, when the two arms 110 are of equal length. As shown in FIG. 1B, if the length of the first arm and the second arm of the light-sensitive molecule 100 differ, then the moiety 130 will be located asymmetrically within the light-sensitive molecule 100. In addition, the spacing between the two arms 110 may vary with moieties of various sizes or by bonding the two arms 110 to various sites on the moiety 130, as long as a stable is maintained.

The moiety 130 may include a functional group, for example, a sulfide, a thiol, or a isonitrile, that covalently bonds to a metal coating, for example, gold, palladium, or platinum, or, for example, to trichlorosilane or trialkoxylsilane, which covalently bond to conductive oxides, such as indium doped titanium oxide, that form the probe of the scanned-proximity probe microscope.

Referring to FIG. 2, when the light-sensitive molecule 100 is attached to a probe 230, for example, a probe of a scanned-proximity probe microscope, a molecular manipulator 200 may be made. In various exemplary embodiments, the probe 230 may comprise a tip or a line, i.e., a linear extension of the tip, as is well known in the art. In various exemplary embodiments, the probe material may comprise, for example, silicon or a ceramic, such as silicon dioxide or aluminum oxide. A coating 210 may be applied to the probe, where the coating 210 may comprise a metal, for example, gold, palladium, or platinum. In various exemplary embodiments, trichlorosilane or trialkoxylsilane, which covalently bond to a probe comprising a conductive oxide, such as indium doped titanium oxide, may comprise the coating 210. The functional group of the moiety of the light-sensitive molecule 100 may covalently bond to the probe 230 or when a coating 210 is present to the coating 210.

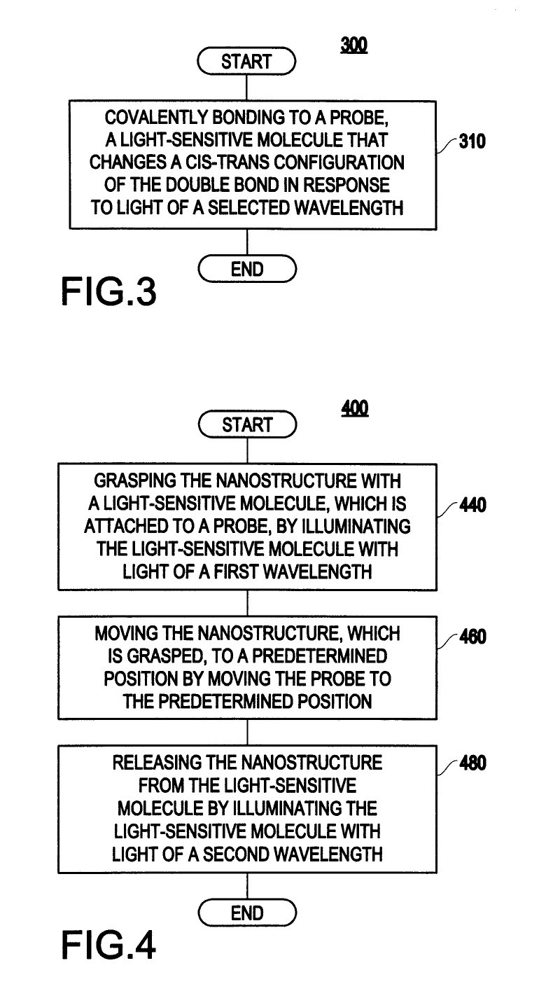

FIG. 3 illustrates a flowchart 300 of an exemplary embodiment of a method of making the molecular manipulator 200 of FIG. 2. In various exemplary embodiments, the method of making a molecular manipulator comprises covalently bonding 310 to a probe, a light-sensitive molecule that changes a cis-trans configuration of a double bond in response to light of a selected wavelength.

In various exemplary embodiments, the probe may constitute a probe or a sensor of a scanned-proximity probe microscope. For example, a selected first wavelength of light, comprising visible light or infra-red light, may change the cis-trans configuration of the double bond of the light-sensitive molecule in order to grasp a nanostructure, while a selected second wavelength of light, comprising visible light or infra-red light, may change the cis-trans configuration of the double bond of the light-sensitive molecule in order to release a nanostructure.

FIG. 4 illustrates a flowchart 400 of an exemplary embodiment of a method of moving a nanostructure with the molecular manipulator, described above. In various exemplary embodiments, the method of moving a nanostructure may comprise grasping 440 the nanostructure with a light-sensitive molecule, which is attached to a probe, for example, a probe of a scanned-proximity probe microscope, by illuminating the light-sensitive molecule with a first wavelength of light to change a double bond from a trans configuration to a cis configuration within the light-sensitive molecule, moving 460 the grasped nanostructure to a predetermined position by moving the probe to a predetermined location, and releasing 480 the nanostructure from the light-sensitive molecule by illuminating the light-sensitive molecule with a second wavelength of light to change the double bond from the cis configuration to the trans configuration. Moving the probe, for example, a probe of a scanned-proximity probe microscope, into proximity with the nanostructure may be accomplished by using the tip of a probe in an AFM mode.

In various exemplary embodiments, the probe may comprise a sensor, which may measure optical absorption, magnetism, etc., or may comprise a line or a tip, which may be deflected by atomic forces of a nanostructure.

While the present invention is described in terms of exemplary embodiments, those skilled in the art will recognize that the invention can be practiced with modifications within the spirit and scope of the appended claims. For example, the present invention may be used to repair a circuit, which contains nanoparticles as components, or to construct a nanostructure, which cannot be fabricated by conventional lithographic processes.

Furthermore, it is noted that Applicants' intent to encompass equivalents of all claim elements, even if amended later during prosecution.

We claim:

1. A method of moving a nanostructure, comprising:
grasping the nanostructure with a light-sensitive molecule, which is attached to a probe, by illuminating the light-sensitive molecule with light of a first wavelength;
moving the nanostructure, which is grasped, to a predetermined position by moving the probe to the predetermined position; and
releasing the nanostructure from the light-sensitive molecule by illuminating the light-sensitive molecule with light of a second wavelength.

2. The method of moving a nanostructure of claim 1, wherein the grasping the nanostructure comprises changing a double bond from a trans configuration to a cis configuration within the light-sensitive molecule.

3. The method of moving a nanostructure of claim 1, wherein changing a double bond from a trans configuration to a cis configuration comprises changing an azo double bond from a trans configuration to a cis configuration

4. The method of moving a nanostructure of claim 1, wherein the releasing the nanostructure comprises changing a double bond from a cis configuration to a trans configuration within the light-sensitive molecule.

5. The method of moving a nanostructure of claim 1, wherein changing a double bond from a cis configuration to a trans configuration comprises changing an azo double bond from a cis configuration to a trans configuration

6. The method of moving a nanostructure of claim 1, further comprising:
moving the probe into a proximate position with the nanostructure by using an atomic force mode of operation of a scanned-proximity probe microscope.
